(19) United States
(12) Patent Application Publication
(10) Pub. No.: US 2002/0005679 A1
(43) Pub. Date: Jan. 17, 2002

(54) METHOD AND APPARATUS FOR IMPROVING A FLEXURE STAGE

(76) Inventors: VIRGIL B. ELINGS, SANTA BARBARA, CA (US); DAVID GRIGG, VENTURA, CA (US); JOHN A. GURLEY, SANTA BARBARA, CA (US)

Correspondence Address: JAMES E NILLES, NILLES & NILLES, 777 EAST WISCONSIN AVENUE, SUITE 2000, MILWAUKEE, WI, 532025345

(21) Appl. No.: 08/893,367

(22) Filed: Jul. 15, 1997

(51) Int. Cl. H04R 17/00; H01L 41/08; G21K 7/00; H01L 41/04

(52) U.S. Cl. 310/323.12; 310/328; 250/307; 29/25.35

(57) ABSTRACT

A method of tuning or trimming a flexure stage to substantially constrain a workpiece carried by the flexure stage's free end from moving along an axis of motion that does not contain a desired path of free end travel. In the case of an XY flexure stage, measures are incorporated into the flexure stage to prevent simple out-of-plane motion (either linear or non-linear), rolling, pitching, or combinations of all three, as well as out-of-axis motion where desired. A preferred tuning technique begins with initially aligning the flexure stage's actuator so that its highest off-axis force component extends as much as possible within the plane of desired motion, followed by positioning the actuator on the flexure stage so as to eliminate as much as possible simple out-of-plane motion and accompanied if necessary by incorporating additional measures to eliminate as much as possible roll or pitch motion and residual simple out-of-plane motion. These additional measures may include attaching a wire guide structure to the flexure stage, removing materials from one or more piezo end flexures, adding materials to or removing materials from one or more flexure points or other locations of the flexure frame, and/or adding a second actuator that imposes net out-of-plane forces on the flexure frame free end that at least partially offset those imposed by the first actuator. The resulting tuned flexure stage exhibits substantially less out-of-plane and out-of-axis motion throughout the operational range of its actuator.

### BACKGROUND OF THE INVENTION

1. Field of the Invention

The invention relates to flexure stages and, more particularly, relates to a method of adjusting at least one operational parameter of a flexure stage to at least substantially prevent motion of the flexure stage's free end out of the desired path of free end travel upon operation of its actuator and hence to reduce out-of-plane or off-axis movement of a workpiece mounted on the free end to within acceptable parameters. The invention additionally relates to a flexure stage incorporating measures to at least substantially prevent at least one component of motion of its free end out of the above-described desired path.

2. Discussion of the Related Art

Flexure stages are widely used for effecting precisely-controlled motion of a workpiece. Flexure stages are also used in a variety of applications to magnify the effect of a piezo stack or other expandable actuator so that the ratio of movement of the workpiece to actuator expansion is on the order of 10:1 or 20:1. Applications are myriad. Flexure stages can be used to support sensors for hard drive testers, drive elements in hard drives, or workpieces or tooling elements in machining applications such as diamond turning machines, grinding machines, milling machines, etc. A flexure stage can also be used to transport a sensor, or sample for use in a measurement application such as a scanning probe microscope or the like.

A flexure stage comprises one or more flexure elements, each of which is designed to translate a workpiece along a specific axis. Each flexure element is typically constructed from rigid components connected by flexible joints called flexures. The flexures are constructed to only allow bending in a single plane. The typical flexure element consists of a flexure frame on which is mounted an expandable actuator. The flexure frame includes a fixed end mounted on a support, and a free end spaced from the fixed end and supporting a sensor, a tool holder, and a tool or some other workpiece to be translated. The actuator acts on the free end to cause the free end to translate in a desired direction (hereafter the “X” direction).

The simplest type of flexure stage, generally known as a “single axis,” employs a single flexure element. Alternatively, two flexure elements can be coupled together (known as an “X-Y flexure stage”) capable of effecting movement of the desired workpiece in both the X direction and the Y direction. A third flexure element could be added to also effect movement of the workpiece in the vertical “Z” direction, thereby producing an “X-Y-Z flexure stage.” Flexure elements can be fabricated in a variety of ways. Two common geometries include a single ended flexure element and a double-ended flexure element. In the simplest case, a single ended flexure element consists of one fixed end and one free/moving end connected via a single set of flexures. For the double-ended flexure element there exist two fixed ends on either side of the free/moving end connected via two sets of flexures, usually in a symmetric fashion. Flexure stages of these and other types are commercially available, e.g., from Piezosystem Jena, Polytec, and Physik Instrumente, and are sold on instruments such as the metrology scanner on Digital Instruments' atomic force microscope.

The typical flexure element is designed to promote motion of the free end in the XY plane and to inhibit motion in the Z plane. Towards this end, the flexure frame of the flexure element is much thicker (more resistant to bending) in the Z direction than in the X direction. Flex points or flex notches are often formed at the corners of the flexure frame and possibly at other locations to promote parallelogram-type movement of the free end of the flexure stage relative to the fixed end within the XY plane. However, it has been discovered that these measures are imperfect. Piezo stacks and other actuators seldom move perfectly axially but instead bow or twist during operation. By applying net torque out of the XY plane, this bowing or twisting usually results in movement of the flexure stage free end out of the XY plane in a simple or complex motion (either linearly or nonlinearly), in a pitching motion (i.e., along the X axis in a fore-to-aft manner), in a rolling motion (i.e., along the Y axis in a side-to-side manner), or in a combination of two or more of these motions.

The magnitude of motion out of the XY plane compared to the magnitude of motion within the XY plane is typically relatively small and is considered acceptable error in many applications. However, it has been discovered that the magnitude of outof-plane motion of many commercially available flexure stage free ends is not acceptable in all applications. For instance, in scanning probe microscopes and other high-accuracy instruments, it is often desirable to limit out-of-plane (Z) motion of the sensor serving as the workpiece to within a few nanometers upon a free end displacement on the order of 100 micrometers to 140 micrometers in the XY plane. That is comparable to seeking less than a centimeter of out-of-plane motion in over one mile of in-plane motion! Currently-available flexure stages are incapable of achieving this degree of precision.

While the necessary precision is being discussed largely in terms of motion out of the XY plane, it is important to note that the techniques discussed herein may be applied to restricting motion to a single axis or path rather than an entire plane. The invention is intended to encompass these applications as well.

### OBJECTS AND SUMMARY OF THE INVENTION

It is therefore a principal object of the invention to provide a method of tuning or trimming a flexure stage so as to at least substantially prevent movement of a workpiece carried by the flexure stage free end out of its desired path of operation, be it an axis, a plane or a path in one two or all three dimensions, throughout the operational range of the flexure stage. The method includes imposing a force on a flexure stage to attempt to drive a free end of the flexure stage to move in a desired path relative to a fixed end of the flexure stage, detecting motion of a portion of the flexure stage out of the desired path, and then adjusting an operational parameter of the flexure stage to at least substantially prevent motion of the free end out of the desired path upon subsequent imposition of the force on the flexure stage.

Preferably, adjustment includes first moving the piezo stack or other actuator relative to the flexure frame in order to minimize as much as possible simple out-of-plane motion, followed if necessary with altering a physical characteristic of the flexure stage to eliminate any remaining simple out-of-plane motion as well as roll and/or pitch. These physical characteristics can be adjusted in a number of ways including: (1) adding material to or removing material from the flexure frame, (2) removing material from the piezo end flexure, and (3) adding a second actuator that imparts net out-of-plane force components on the flexure stage that at least partially offset net out-of-plane force components imposed on the flexure stage by the first actuator.

A particularly useful solution to the problem of free end twisting and of the resulting roll and pitch resides in attaching a structure stiff in the Z direction, such as a guide wire attached to the flexure stage. The preferred guide structure comprises at least one (and even more preferably two) wires each of which has a generally central portion attached to the free end and has a pair of fixed ends. The wires are tensioned to impart a counterbalancing torque on the free end upon free end twisting.

In the guide, if the flexure stage is a so-called X-Y flexure stage formed from two interconnected flexure elements extending at an angle from a common vertex that is located between the fixed end and the free end, then the guide preferably includes at least first and second wires extending (1) in parallel with one another, and (2) orthogonally with respect to the designated plane. The first wire is operatively coupled to the flexure stage proximate the free end, and the second guide wire is operatively coupled to the flexure stage proximate the vertex. Preferably, the guide further comprises a third wire extending in parallel with the first and second wires and operatively coupled to the flexure stage proximate the free end.

Wire guides or other similar guides have been found to increase the resonant frequency of the overall flexure stage and hence to increase the available speed at which they can be operated accurately.

Still another possible technique for tuning a flexure stage is to position a second actuator on the flexure stage in order to impose an out-of-plane force component on the flexure frame that at least substantially offsets a net out-of-plane force component imposed on the flexure frame by the first actuator so that the free end moves substantially solely in the designated plane. The second actuator could be used to solely correct for errors created by the first, either closed loop or open loop, or may be used to both correct error and to apply force to assist motion in the intended direction.

Another object of the invention is to provide an improved flexure stage that incorporates measures to at least significantly reduce motion of a workpiece carried by the free end of the flexure stage out of a desired path of motion upon operation of the actuator. For instance, the method used for coupling the actuator to the flexure system could be reduced in size or replaced by a ball bearing or some other structure approximating a point contact, or materials could be added to or removed from selected portions of the flex notches in the flexure frame.

These and other objects, features, and advantages of the invention will become apparent to those skilled in the art from the following detailed description and the accompanying drawings. It should be understood, however, that the detailed description and specific examples, while indicating preferred embodiments of the present invention, are given by way of illustration and not of limitation. Many changes and modifications may be made within the scope of the present invention without departing from the spirit thereof, and the invention includes all such modifications.

### BRIEF DESCRIPTION OF THE DRAWINGS

Preferred exemplary embodiments of the invention are illustrated in the accompanying drawings in which like reference numerals represent like parts throughout and in which:

FIG. 1 is a side elevation view of an X-Y flexure stage to which the present invention is applicable;

FIG. 2 is a sectional elevation view taken generally along the lines 2-2 in FIG. 1;

FIG. 3 is a perspective view of a piezo stack serving as an actuator for the flexure stage of FIG. 1 and of the associated piezo end flexure for connecting the piezo stack to the flexure frame;

FIG. 4 schematically represents an X flexure stage to which the present invention is applicable;

FIG. 5 is a side elevation view schematically representing the motion of the flexure stage of FIG. 4;

FIG. 6 is a flow chart representing a preferred technique for tuning or trimming a flexure stage in accordance with the present invention;

FIGS. 7 and 8 are a right side elevation view and a sectional front side elevation view, respectively, illustrating the tuning or trimming of a flexure stage by movement of a flexure-stage's actuator within the associated flexure frame;

FIG. 9 is a perspective view illustrating twisting of a flexure stage as well as the removal of material from a portion of the flexure frame so as to counteract twisting tendencies and the resulting roll and pitch;

FIGS. 10 and 11 are a right side elevation view and a sectional front side elevation view, respectively, of an X flexure stage incorporating a guide structure to reduce out-of-plane motion and to increase the flexure stage's resonant frequency;

FIG. 11A is a sectional plan view taken along the lines 11A-11A in FIG. 11;

FIG. 12 is a perspective view of an X-Y flexure stage incorporating a guide structure similar to that employed by the X flexure stage of FIGS. 10, 11, and 11A;

FIGS. 13 and 14 are a right side elevation view and a sectional front side elevation view, respectively, of a flexure stage in which a piezo end flexure of the flexure stage is thinned to reduce out-of-plane motion;

FIGS. 15 and 16 are a right side elevation view and a sectional front side elevation view, respectively, of a flexure stage in which a piezo end flexure is replaced by a ball-and-socket mechanism to cause the contact area between the piezo stack and the flexure frame to approximate a point to reduce out-of-plane motion;

FIGS. 17 and 18 are a right side elevation view and a front side elevation view, respectively, of a flexure stage in which material is removed or thinned from selected portions of the flexure frame to reduce out-of-plane motion;

FIGS. 19 and 20 are a right side elevation view and a partially cut-away front side elevation view, respectively, of a flexure stage in which material is added to selected portions of the flexure frame to reduce out-of-plane motion;

FIGS. 21 and 22 are a right side elevation view and a sectional front side elevation view, respectively, of a flexure stage which incorporates a second actuator that imposes net out-of-plane forces on the flexure stage free end that offsets net out-of-plane forces imposed on the flexure stage free end by the first actuator;

FIGS. 23 and 24 are a right side elevation view and a sectional front side elevation view, respectively, of a flexure stage and a sensor arrangement usable to detect out-of-plane motion of the flexure stage; and

FIGS. 25-27 are right side elevation views of alternative flexure stages with which the invention is applicable.

### DETAILED DESCRIPTION OF THE PREFERRED EMBODIMENTS

1. Resume

Pursuant to the invention, a method is provided of tuning or trimming a flexure stage to constrain the movement of a workpiece carried by the flexure stage's free end to a desired path of free end travel . For example, in the case of an XY flexure stage, measures are incorporated into the XY flexure stage to prevent simple out-of-XY plane motion (either linear or nonlinear), rolling, pitching, or combinations of all three. A preferred tuning technique begins with initially aligning the flexure stage's actuator in reference to the flexure frame so that its highest off-axis force component extends as much as possible within the designated plane of motion, followed by positioning the actuator on the flexure stage so as to eliminate as much as possible simple out-of-plane motion and accompanied if necessary by incorporating additional measures to eliminate as much as possible roll or pitch motion and residual simple out-of-plane motion. These additional measures may include attaching a guide structure to the flexure stage, removing materials from one or more piezo end flexures, adding materials to or removing materials from one or more flexure points or other locations of the flexure frame, and/or adding a second actuator that imposes net out-of-plane forces on the flexure frame free end that at least partially offset those imposed by the first actuator. The resulting tuned flexure stage exhibits substantially less out-of-plane motion throughout the operational range of its actuator than the flexure stage prior to tuning.

2. Flexure Stage Construction and Characteristics

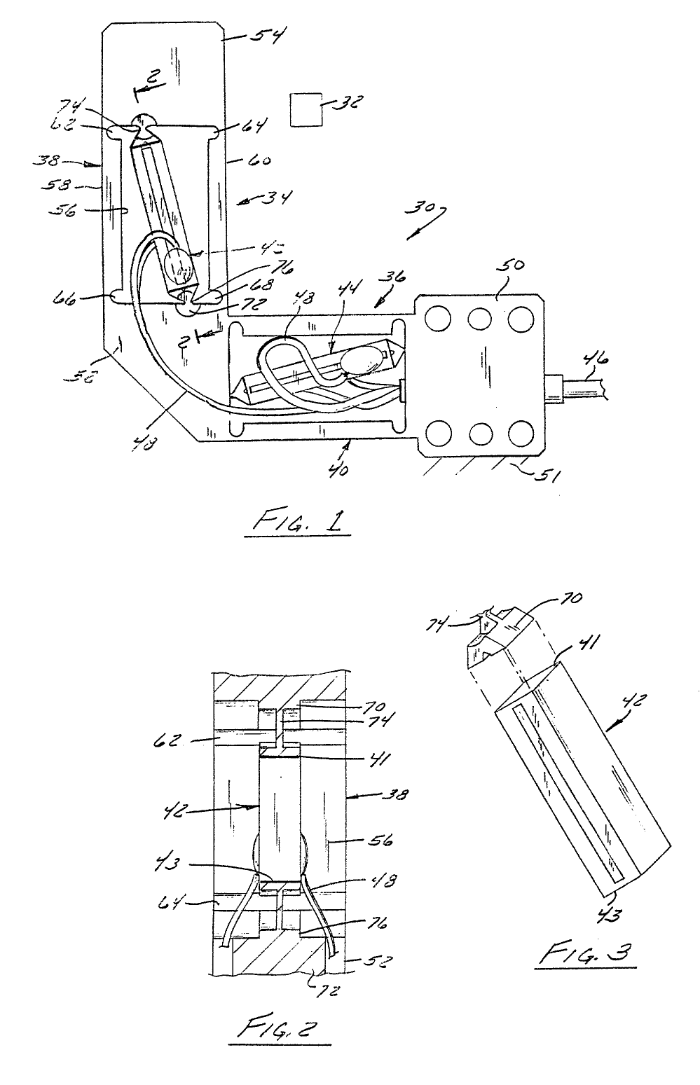

The need for and manner of fine tuning a flexure stage can be better appreciated from an understanding of the structure of a typical flexure stage and its operational tendencies. Referring initially to FIGS. 1-3, an X-Y flexure stage 30 is illustrated to which the present invention is applicable. The flexure stage 30 may be used to translate any workpiece for which precisely controlled motion within a plane is desirable. It is particularly-well suited for translating a sensor 32 of the type used, for example, in scanning probe microscopy. The flexure stage 30 can be used to translate a sensor 32 in either the X direction or the Y direction without moving the sensor 32 in the Z direction, i.e., out of the page as seen in FIG. 1.

The flexure stage 30 includes an X flexure element 34 and a Y flexure element 36 which are connected integrally to one another and which are designed to effect movement of the sensor 32 in the Y direction and X direction, respectively (the “X direction” and “Y direction” are defined below). Each flexure element 34 or 36 includes a parallelogram-type flexure frame 38 or 40 one end of which is designed to move relative to the other. Not all flexure frames are of parallelogram type, and the invention is intended to apply to other types, but the parallelogram type is used throughout for demonstrative purposes. For the sake of convenience, the end of the flexure frame that is designed to move will hereafter be referred to as the “free end,” and the end that serves as a frame of reference for this movement will hereafter be referred to as the “fixed end.” A fixed end 50 of the Y flexure element 36 is rigidly attached to an underlying support 51, such as a Z stage of a scanning probe microscope (not shown), or a course positioner for machine tools. In the example, the X flexure element 34 extends perpendicularly from the Y flexure element 36 such that its fixed end merges with and is constituted by the free end of the Y flexure element at a vertex 52. The free end 54 of the X flexure element supports, or is mechanically linked to, the sensor 32 in a conventional manner.

A first actuator 42 is mounted on the flexure frame 38 for effecting movement the free end 54 of the X flexure element 34 relative to the fixed end 52. A second actuator 44 is mounted on the flexure frame 40 for effecting movement of the free end 52 of the Y flexure element 36 relative to the fixed end 50. Both actuators 42 and 44 are supplied with electrical power via a cable 46 composed of several wires 48.

Apart from the connections of their fixed and free ends to other components, the X and Y flexure elements 34 and 36 are of essentially identical construction, and the problems presented by their operation are also essentially identical. Hence, the details of only the X flexure element 34 will described but will pertain to both for the sake of conciseness.

In the illustrated embodiment, the X flexure element 34 comprises the flexure frame 38 which is formed from a relatively rigid material such as metal, plastic or ceramic. The flexure frame 38 presents the fixed end 52, the free end 54, and a cavity 56 formed therein between the free end 54 and the fixed end 52. The cavity 56 is bordered at its inner end by the fixed end 52 and at its outer end and the free end 54. The cavity 56 is also bordered at its sides by a pair of parallel legs 58 and 60 extending generally longitudinally from the inner edge surface of the cavity 56 to the outer edge surface. The legs 58 and 60, as well as the remainder of the flexure frame 38, are much thicker in the Z direction (i.e., in the direction perpendicular to the XY plane) than in their other dimensions to inhibit movement out of the XY plane. Flex notches 62, 64, 66, and 68, sometimes called flexures, are formed at the opposite ends of each of the legs 58 and 60 to promote parallel movement of the legs 58 and 60 relative to one another and to promote parallel movement of the free end 54 relative to the fixed end 52. These flex notches 62, 64, 66, and 68 preferably extend the entire thickness of the legs 58 and 60 in the Z direction.

The actuator 42 could comprise any suitable expandable device but preferably comprises a conventional piezo stack. Although the illustrated piezo stack 42 is rectangular in cross-section, it could also be round or another shape. The piezo stack 42 is mounted in the cavity 56 at an acute angle with respect to the longitudinal axis of the flexure frame 38 so as to impose a force on the free end 54 that has components in both the X direction and the Y direction. Mounting the piezo stack 42 at an angle in this manner amplifies the output so that the ratio of flexure stage free end motion in the X direction to piezo stack expansion is on the order of 10:1 or 20:1.

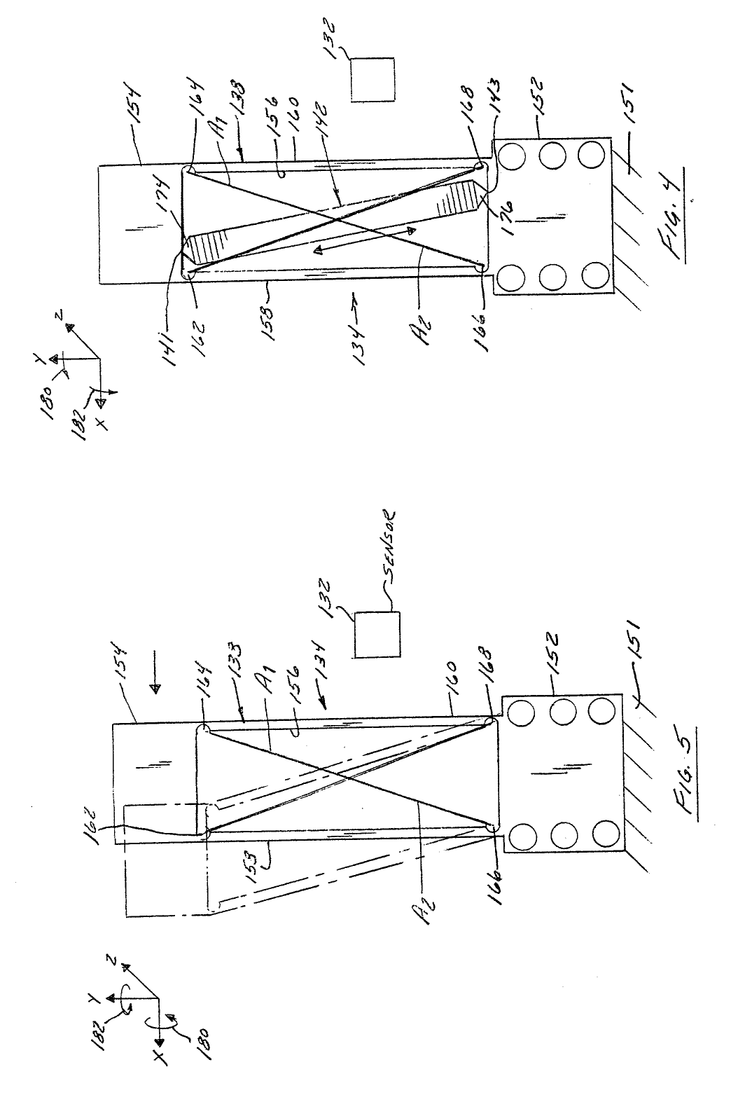

As best seen in FIGS. 2 and 3, the ends 41 and 43 of the piezo stack 42 are mounted in the cavity 56 by gluing them to metal inserts 70 and 72 that in turn are bonded in the ends of the cavity 56. The inserts 70 and 72 are machined to have a shape that is generally triangular when viewed in side elevation as seen in FIG. 1. The resulting line of contact between the piezo stack 42 and the flexure frame 38 extends in the Z direction across at least a substantial width of the piezo stack 42. This area of contact, being thinner in the direction orthogonal to the Z direction than the corresponding width of the piezo stack 42, represents another flex point 74 or 76 hereafter referenced a “piezo end flexure.” As shown in FIGS. 2 and 3, the flexures 70 and 72 have been machined further to reduce the contact to a near point as discussed above.

The problems arising during operation of the piezo stack 42 that result in out-of-plane motion of the free end 54 and sensor 32 can occur whether the flexure stage is an X-Y flexure stage of the type illustrated in FIGS. 1-3, a flexure stage in which two flexure elements are mounted end-to-end in a mirror image such that their free ends abut one another, or a simple X flexure stage. Because the problems encountered by the invention are most easily understood with respect to a single or X flexure stage, much of the discussion that follows will center on a single or X flexure stage, it being understood that the invention is equally applicable to an X-Y flexure stage or other flexure stages (examples of some of which are discussed in Section 5 below) that are designed to permit motion along a single axis or along some other path. Thus, while the invention will be discussed primarily with respect to constraining the flexure stage free end from movement out of a designated plane, the invention is also applicable to any application in which it is desired to constrain the free end of a flexure stage to movement along at least one axis or path. Hence, references herein to constraining movement to a desired path should be construed broadly to include constraint of motion according to the number of axes of motion the flexure stage is designed to allow. For example, where a flexure frame is designed to permit motion in two axes, X and Y for example), thereby describing a plane, motion out of the desired path is most simply described as “out-of-plane” motion. Where a flexure frame is designed to permit motion in a single axis, motion out of the desired path is most simply described as “out-of-axis” motion. In all cases, the potential range of motion is limited by the ordinary mechanical constraints of typical flexure frames. The function of the invention is to constrain the free end from at least one component of motion out of a desired path whether in one, two, or three dimensions. Hence, references herein to detecting or reducing motion out of a desired path should be construed to mean detecting, reducing, or otherwise addressing at least one component of motion out of the desired path. Other components of motion out of the desired path could also exist and could also but not necessarily be addressed.

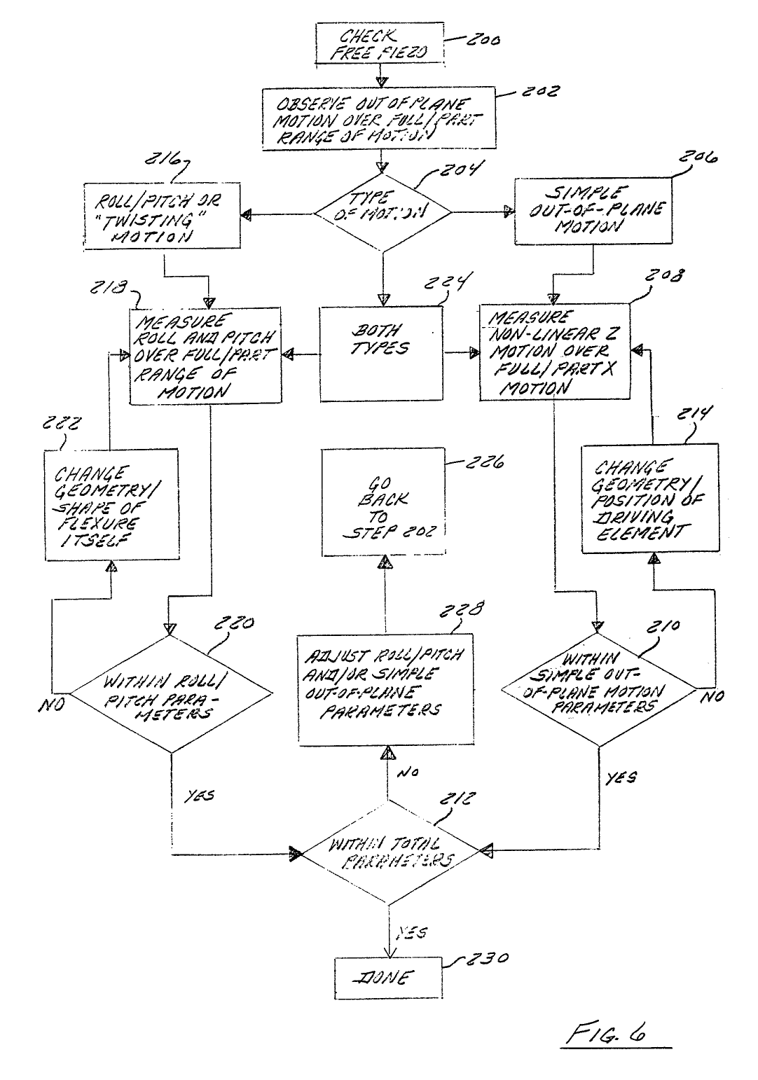

Referring now to FIGS. 4 and 5, a single or X flexure stage 134 is illustrated that is identical to the X flexure element 34 of FIGS. 1-3 with the exception that the fixed end 152 is adapted to be connected to the underlying support 151 directly rather than through an intermediate flexure element. Elements of the flexure stage 134 corresponding to the flexure element 34 therefore are designated by the same reference characters, incremented by 100. These elements include (1) a frame 138 having a fixed end 152, a free end 154, and legs 158 and 160 in which are formed flex notches 162, 164, 166, and 168, and (2) an actuator 142 having ends 141 and 143 and associated piezo end flexures 174 and 176. The primary range of motion of the flexure stage 134 is in the X direction, with motion in the Y direction arising because of parabolic shortening of the flexure stage 134 during movement. This type of parabolic shortening is characteristic to many single ended flexures, but does not usually occur in double ended flexures. The free end 154 and sensor 132 therefore move in the XY plane and are constrained from motion in the Z direction (i.e., into and out of the page in FIGS. 4 and 5).

It is important to note at this point that the “X” axis is the axis of intended motion rather than the axis of the free end 154 itself. It should also be noted at this point that, as discussed above and as can be seen in FIGS. 4 and 5, the sensor 132 is necessarily offset from the centroid of the free end 154 due to physical limitations of the system. Were it not for this offset, roll and pitch (as defined below) might not present as great a problem, as they do in the current example. In the general case, roll and pitch and yaw may lead to out-of-plane or out of axis motion of the sensor 132 and usually must be addressed if elimination of out-of-plane and/or out-of-axis motion is desired. Further, such out-of-plane and out of axis motion may in many cases effect over-all performance of the application, for reasons other than relative placement of the workpiece.

It has been discovered that, in practice, expandable actuators such as the piezo stack 142 do not move perfectly axially upon expansion, leading to various types of out-of-plane motion of the free end 154 of the flexure stage 134 with respect to the XY plane. Each of these out-of-plane motions will now be described.

The first type of out-of-plane motion encountered by flexure stages is simple out-of-plane motion resulting from bowing of the piezo stack 142 in a single plane that is not in the XY plane. This bowing is best understood if the piezo stack 142 is imagined outside the flexure such that when a voltage is applied, the stack bends or twists as it elongates. This bowing gives rise to so-called “first order” error in which the free end 154 moves either linearly or nonlinearly out of the XY plane. Thus, the free end 154 can be forced out of the intended plane of motion due to the out-of-plane forces created by the bowing. For example, bowing in the form of movement of the ends of the piezo stack 142 out of the page and towards the viewer in FIG. 5 would generally tend to cause the free end 154 to move into the page or away from the viewer.

Twisting may also occur either alone or combine with bowing to give rise to second order errors. Twisting occurs when the far end of the piezo stack 142 turns relative to the near end. This twisting generates moments that lead to pitching and rolling of the flexure stage free end 154. “Roll” may be defined as movement in the direction of the Y axis or about the X axis from side-to-side. Roll is represented by the arrow 180 in FIGS. 4 and 5. “Pitch” may be defined as movement in the direction of the X axis or about the Y axis in a fore-to-aft manner. Pitch is represented by the arrow 182 in FIGS. 4 and 5. Roll and/or pitch may also occur due to bowing of the piezo stack in more than one plane. Of course, these types of motion are not mutually exclusive, and the free end 154 may encounter a combination of two or all three types of motion during operation of the piezo stack 142. In the general case, the geometry of the contact between an actuator and a flexure frame will control what sort of undesirable motion is created the characteristics of the expanding actuator.

Referring again to FIGS. 4 and 5, roll and pitch can be better understood by recognizing that, due to the parallelogram structure of the flexure frame 138, and due to the canted or inclined orientation of the piezo stack 142 within the cavity 156, roll and pitch actually (though they are defined relative to the axis of motion) occur about axes A1 and A2 that extend diagonally between the flexure notches 164, 166, and 162, 168 as illustrated. In the illustrated embodiment, roll and pitch due to piezo stack bowing will be most severe along the axis A1 because the piezo stack 142 is pushing more perpendicularly to that axis A1 than to the axis A2. Conversely, roll and pitch due to piezo stack twisting will be most severe along the axis A2 which is more nearly parallel with the axis of the piezo stack 142. However both roll and pitch can and do occur simultaneously about both axes A1 and A2.

The complexity of the coupling between X and Y motion (and Z motion if included) and the flex of the actuator defies use of a single model to discuss all of the potential combinations and effects, thus the discussion here uses a single model to demonstrate that complexity and methods of attacking it rather than attempting to detail all possible solutions.

3. Description of Basic Adjustment Technique

Having defined and explained the concepts of “out-of-plane,” and “out-of-axis,” motion, and deviation from a desired path as the more general case, as well as describing the factors contributing to out-of-plane motion in the example, the manner in which operational characteristics of the flexure stage 134 can be adjusted to eliminate out-of-plane motion or at least to reduce it to within acceptable parameters may now be described. A preferred general technique for this adjustment is described first, followed by a discussion of several non-mutually exclusive alternative mechanisms for its implementation.

Stated in its most basic concept, the invention relates to the identification of flexure stage out-of-plane motion and to the adjustment of one or more of the flexure stage's operational parameters to reduce out-of-plane motion to within acceptable parameters. The term “operational parameter” as used herein is broadly construed to include the physical structure of one or more components of the flexure stage as well as reaction of the flexure stage to internal or external stimuli. The adjustment can take the form of rearranging the flexure stage components relative to one another, physically altering the structure of the flexure stage 134, adding external guides, and/or adding an additional actuator that offsets out-of-plane forces imposed by the actuator 142.

Referring now to FIG. 6, a preferred closed-loop process for effecting this adjustment is illustrated. The process may be performed entirely manually or partially manually with some measurements and even some adjustments being performed automatically. Thus, it should be understood that the invention is intended to include both manual and automatic completion of the iterative processes. The process begins with Step 200 in which the piezo stack 142 (or other actuator if another comparable actuator is used instead of a piezo stack) is tested prior to its mounting in the flexure stage 134 to determine in which plane its bowing motion is the greatest. The piezo stack 142 is then positioned in the cavity 156 such that the greatest component of its bowing motion is located within the XY plane, thus reducing the need for subsequent adjustments.

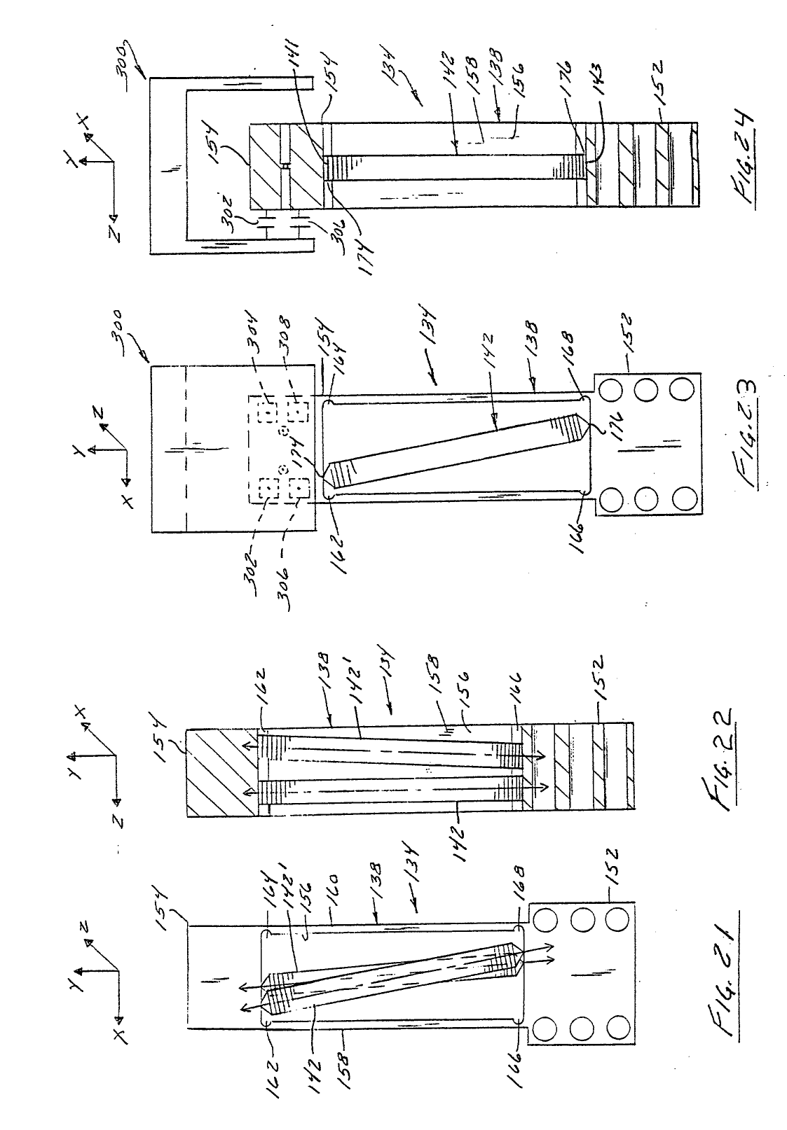

Next, the out-of-plane motion of the flexure stage free end 154 is observed in step 202 over part or all of the range of motion of the piezo stack 142, preferably using a sensor arrangement such as that illustrated in FIGS. 23 and 24. This sensor arrangement includes (1) a sensor jig 300 partially surrounding the free end 154 of the flexure stage 134, and (2) a plurality of capacitance sensors extending between the flexure stage free end 154 and the sensor jig 300. Four sensors 302, 304, 306, and 308 are provided in the illustrated embodiment. The sensors 302, 306 and the sensors 304, 308 are located on opposite sides of the longitudinal centerline of the free end 154. The sensors 302, 304 and the sensors 306, 308 are located above and below the lateral centerline of the free end 154, respectively. The signal from any one sensor provides an indication of the direction and magnitude of simple out-of-plane motion. The direction and magnitude of pitch can be ascertained by comparing the signal from either of the sensors 302 or 306 to the signal from either of the sensors 304 or 308. The direction and magnitude of roll can similarly be ascertained by comparing the signal from either of the sensors 302 or 304 to the signal from either of the sensors 306 or 308. These signals can then be combined in a readily ascertainable manner to identify the type of motion in Step 204 in FIG. 6 as either simple out-of-plane motion or roll and/or pitch motion. The sensing could alternatively be accomplished with an interference microscope or other sensors to view the Z motion of the free end of the flexure over a large enough area to detect pitch, roll, and/or out-of-plane motion.

In the preferred and illustrated embodiment, different adjustment techniques are used to reduce simple out-of-plane motion or other types of out-of-plane motion. When simple out-of-plane motion is identified as indicated in Step 206, the non-linear Z motion is measured over either the full range or part of the range of piezo stack motion in Step 208. The process then determines in Step 210 whether or not the measured simple out-of-plane motion is within an acceptable parameter such as +2.5 nanometers at the free end. If so, the process proceeds to Step 212. If not, an operational parameter of the flexure stage 154 is adjusted in Step 214. This adjustment preferably comprises changing the geometry or the position of the piezo stack 142 as detailed in Section 4(a) below. The process then returns to Step 208, where the motion is again measured, and proceeds through a closed loop consisting of the Steps 208, 210, and 214 until the measured outof-plane motion is within accepted parameters.

If it is determined in Step 204 that the flexure stage free end 154 undergoes motion other than simple out-of-plane motion, the process proceeds to Step 216 and then to Step 218 in which the roll or pitch is measured over a part or full range of motion of the piezo stack 142. The process then determines in Step 220 whether or not the measured roll or pitch is within accepted parameters, such as one to two arc seconds. If so, the process proceeds to Step 212. If not, the process proceeds to Step 222 where the shape or geometry of the flexure frame 138 is changed or adjusted, preferably using one or more of the techniques described in Section 4(b) below, in an attempt to reduce the roll and pitch. Steps 218 through 222 are repeated in a reiterative, closed loop manner as many times as are necessary to reduce the roll and pitch to within accepted operational parameters.

It should be noted at this time that if both simple out-of-plane motion and roll or pitch motion are detected as represented by Step 224, the Steps 206-214 and 216-222 are performed independently of one another to eliminate both types of motion.

Step 212 recognizes the fact that independently addressing simple out-of-plane motion and roll or pitch motion may adversely affect adjustments made in response to the other type of motion. For instance, depending upon the adjustment technique chosen, reducing simple out-of-plane motion may actually tend to exasperate rolling or pitching motion. Hence, after the independent adjustments identified above are completed, the process determines in Step 212 whether or not the flexure stage free end 154 moves entirely within acceptable parameters. If not, an adjustment deemed most likely to correct the detected defect is performed in Step 226, and the process returns to Step 202 via Step 228 for further measurement and possible further adjustment. If so, no further adjustment is required, and the process ends in Step 230.

4. Preferred Adjustment Techniques

Several preferred techniques for eliminating or at least reducing out-of-plane motion will now be described, it being understood that these techniques are neither mutually exclusive nor all-inclusive.

a. Mechanisms for adjusting the geometry or position of driving elements

i. Actuator Position

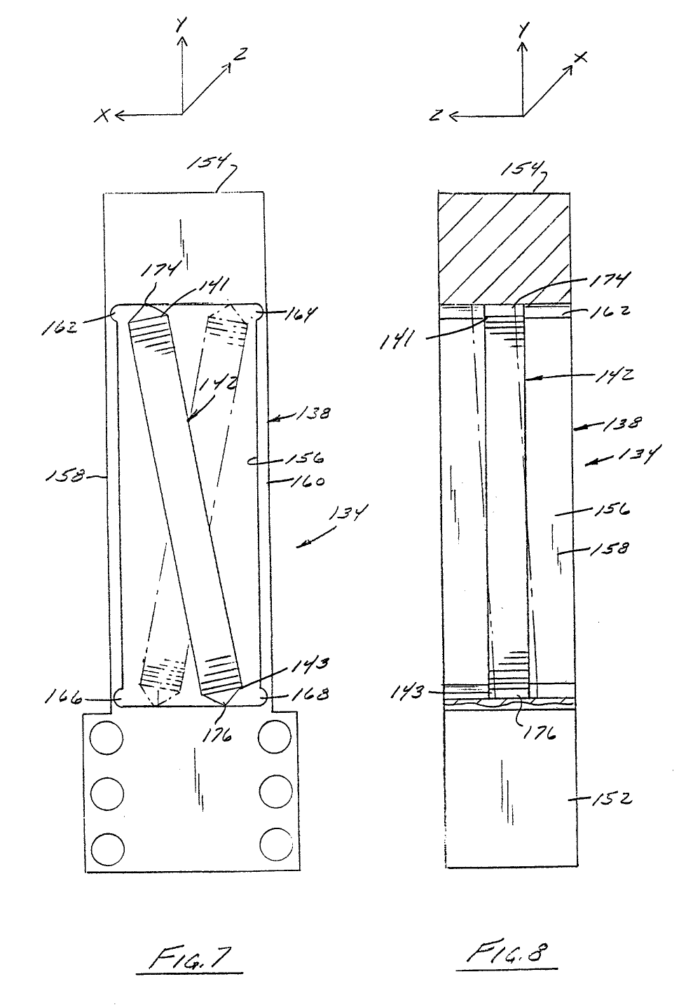

As discussed in Section 3 above, the effects of bowing of a piezo stack 142 or another actuator on out-of-plane motion will vary depending upon the orientation of the piezo stack with respect to the cavity 156. Simple out-of-plane motion and even some components of roll and pitch can be reduced by repositioning the piezo stack 142 within the cavity 156. Repositioning the piezo stack 142 may encompass movement of one or both of its ends in the Z direction, the X direction, or a combination of both. This repositioning is illustrated schematically by FIGS. 7 and 8, which illustrate the preadjusted position of the piezo stack 156 in solid lines and the post-adjusted position in phantom lines.

In the preferred embodiment, after the direction and magnitude of out-of-plane motion are detected as discussed in Section 3 above, the piezo stack position is adjusted in the Y direction by an amount designed or estimated to eliminate this motion. For instance, if a detected bowing motion of the piezo stack results in simple out-of-plane motion of the free end 154 out of the page as seen in FIG. 7 or to the right as seen in FIG. 8, the piezo stack 142 is repositioned so that at least its upper end 141 is repositioned away from this direction of bowing to counteract the bowing effects. Repositioning is preferably performed before the final gluing or soldering of the piezo stack 142 in place, with the motion of the free end 154 being measured after each successive repositioning operation in a closed loop fashion as described in Section 3 above. Only after it is determined that the piezo stack 142 is optimally positioned will it be soldered or glued in place. This adjustment may also be made automatically, prior to or during use.

The positions of both ends 141 and 143 are adjusted in the illustrated embodiment. However, in some instances, it may be desirable to adjust the position of only one end 141 or 143.

ii. Piezo end Flexure Modification

Another technique for compensating for out-of-plane motion involves modifying the contact area between the piezo stack 142 and the flexure frame 138, thereby modifying the piezo end flexure 174 or 176. As discussed above, the typical piezo stack 142 contacts the surface of the flexure frame cavity 156 along the entire width of the piezo stack 142. This relatively thin but long area of contact may translate undesired out-of-plane forces to the flexure stage free end 154 that occur due to bow and/or twist of the piezo stack 142. Conversely, if this contact were just a point contact, the unwanted forces imposed on the free end 154 due to piezo stack bowing and twisting would be substantially less on the free end 154. However, a true point contact is impractical because piezo stack 142 typically imposes from five to fifteen pounds of force on the flexure frame 138 upon expansion. If this force were imposed on a very small point, the resulting pressures could crush the point. The line contact also may act to equalize net torques placed on the flexure frame 138. Hence, alternative solutions that equalize unwanted torques or at least partially obtain the same effect are desirable.

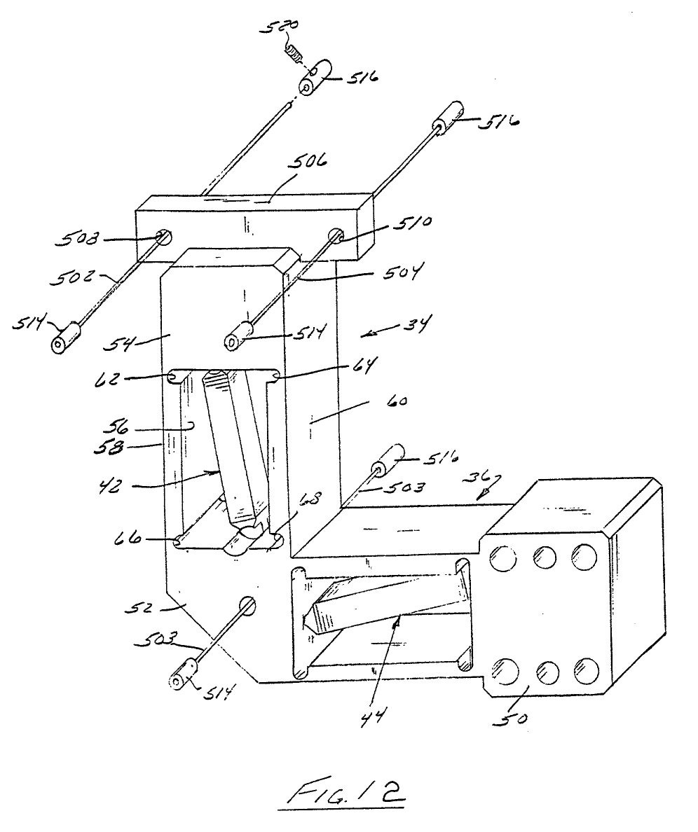

One solution is illustrated schematically in FIGS. 13 and 14. This solution involves the removal of some of the contact surface between the piezo stack 142 and the flexure frame 138 to decrease the contact length and/or change the net torque applied by the piezo end flexure 174 and/or 176. For instance, one or both sides of the piezo end flexure 174 could be partially drilled out to shorten the effective contact length of the upper end 141 of the piezo stack 142 with the flexure frame 138. The decision as to the amount of material to remove, whether or not to remove material from one or both piezo end flexures 174 and 176, or whether to remove material from side of the selected piezo end flexure(s), the other side, or both sides will depend upon the magnitude and direction of out-of-plane forces detected in Step 208 as discussed in Section 3 above. Typically, a relatively small amount of material should be removed from one or both sides of the piezo end flexure 174 and/or 176 at one or both ends of the piezo stack 142 first, the effects of this removal is measured, and then more material is drilled out incrementally until the desired effects are achieved as represented by the loop of Steps 208-214 in FIG. 6. In the illustrated embodiment, material is removed from one side of the piezo end flexure 174 located at the upper end 141 of the flexure stack to create a bore 175. A similar bore is shown in FIG. 12 at the near end of piezo stack 42.

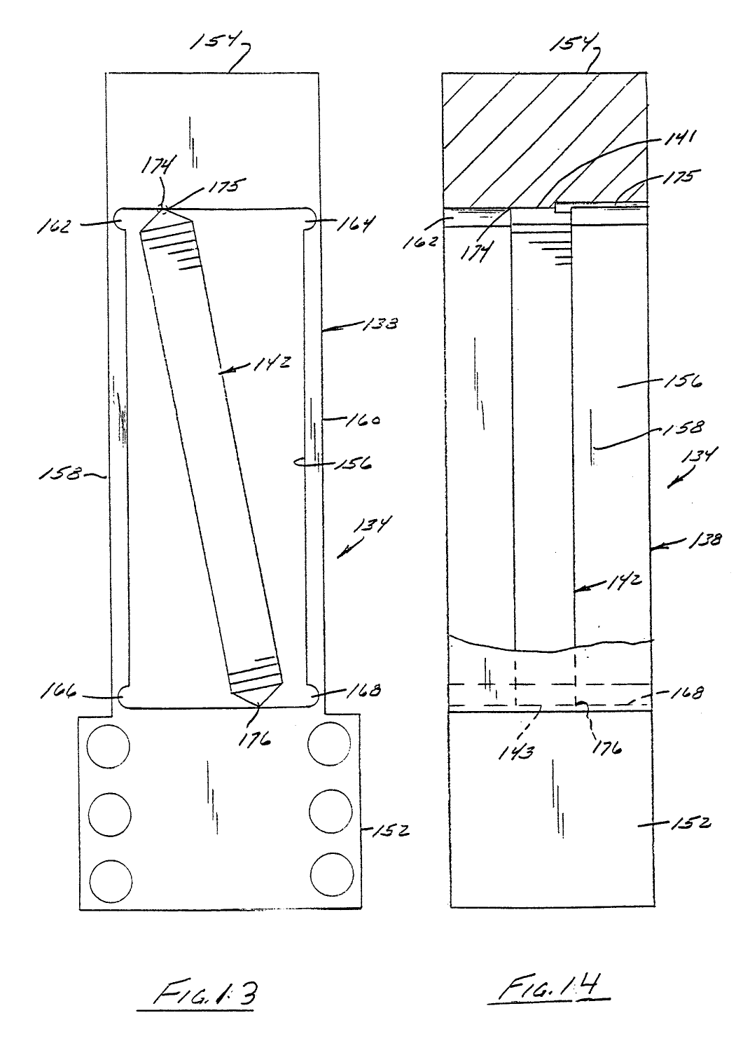

An alternative technique with similar results, illustrated in FIGS. 15 and 16, approximates a point relationship by mounting one or both ends of the piezo stack 142 in the cavity 146 using a ball and socket mechanism 175′. This technique is at least theoretically more effective than reducing the size of the piezo end flexure by drilling but is more difficult and expensive to implement. Further, the torque applied by a line contact may be useful to accomplish the objects of this invention by allowing tuning of those torques by the above methods.

b. Mechanisms for Changing Flexure Geometry or Shape

Adjusting the position of the piezo stack 142 within the flexure stage 134 and/or adjusting the geometry of piezo stack contact with the flexure stage 134 significantly reduces out-of-plane motion due to piezo stack bowing and partially reduce pitching or rolling. However, they are not completely effective. Several techniques for further tuning the flexure stage to further reduce pitching, rolling, and, if necessary, residual simple out-of-plane motion, will now be detailed.

i. Mechanisms for Altering Flexure Frame Geometry

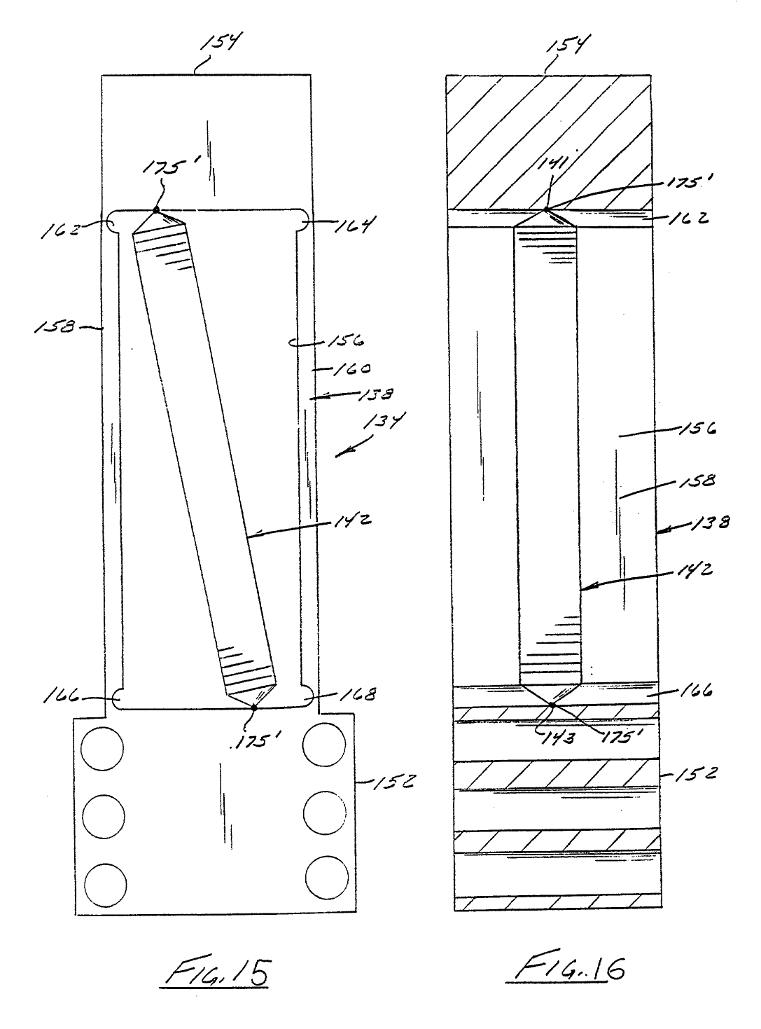

Twist resistance as well as resistance to piezo stack bowing can be enhanced either by removing material from the flexure frame 138 or by adding material to the flexure frame 138. Removal of material lowers the spring constant associated with the flex notch where the material is removed, it also decreases resistance to compression and expansion under tension. There are many ways to remove material to accomplish reduction of spring constant and/or resistance to compression and tension. Two methods of removal of material are illustrated in FIGS. 17 and 18. The first is by cutting material to increase the depth by one or more of the flex notches 162, 164, 166, or 168. Flex notch depth can be increased by removing material from the inside of a flex notch (as seen at 164′). A similar effect may be accomplished by removing material from the leg at a location adjacent a flex notch (as seen at 168′). The amount of thinning, the length of the area to be thinned, and the location of this thinning will depend upon the desired results. If the goal is to reduce residual simple out-of-plane motion due to piezo stack bowing, one end of two or all four of the flex notches 162, 164, 166, or 168 should be thinned. The end of each notch to be thinned is determined by the direction of bowing. Generally speaking, the end towards which the ends of piezo stack 142 bows is the end that is thinned. Hence, if the piezo stack 142 is bowing away from the page and towards the viewer in FIG. 17, material is removed from that end of one or more of the flex notches 162, 164, 166, or 168. One effect of this thinning is to effectively move the flex notch in the Z direction.

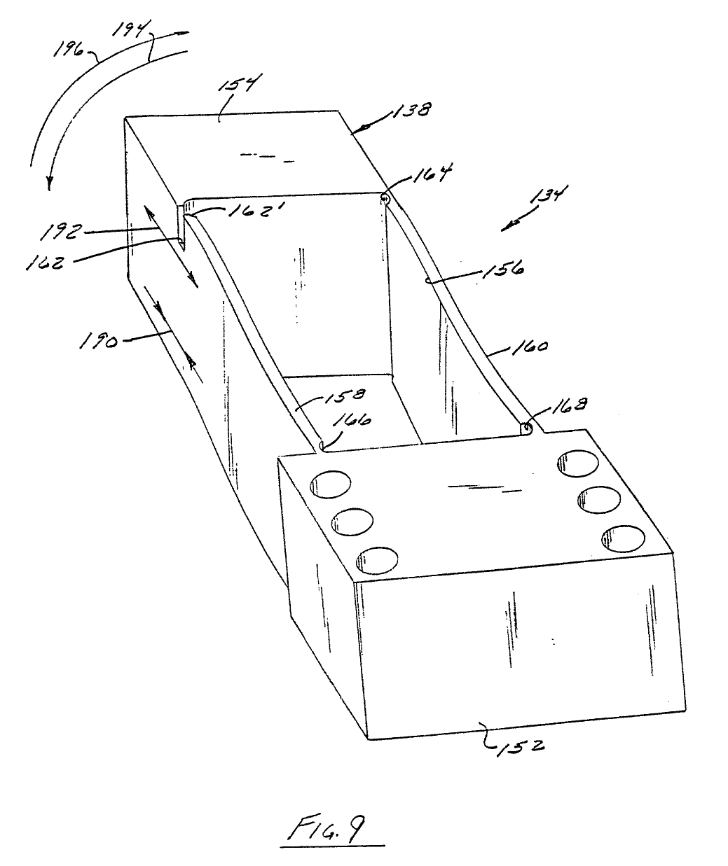

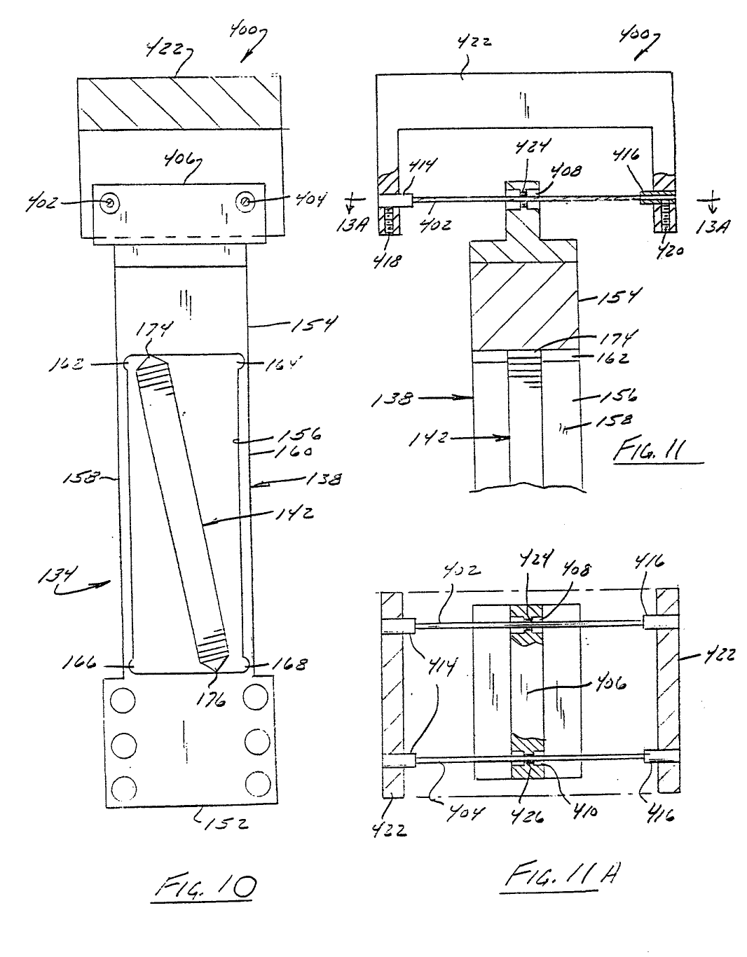

If, on the other hand, one wishes to reduce flexure frame twisting caused either by piezo stack twisting or non-simple piezo stack bowing, then material is removed from some of the flex notches but not others to resist twisting forces and the resultant rolling and pitching motions. FIG. 9 provides an illustrative example. In this example, piezo stack twisting, bowing, or a combination of both compress one side of the flexure frame 138 and expand the other side as represented by the arrows 190 and 192, thereby imparting a counterclockwise twisting motion to the flexure stage 134 as represented by the arrow 194. Cutting the notch 162 deeper (including all the way through as shown in FIG. 9) at its end 162′ in the illustrated manner gives rise to a countervailing torque as represented by arrow 196 that encourages flexure frame movement towards that notch portion 162′ or in a direction opposite to that in which flexure frame twisting tends to occur.

Of course, as with the previously-described techniques, parameter adjustment through material removal preferably is performed in an incremental, closed-loop fashion as represented by the Steps 216-222 in FIG. 6 with the effects of each incremental amount of material on pitch and roll being monitored before additional material is removed.

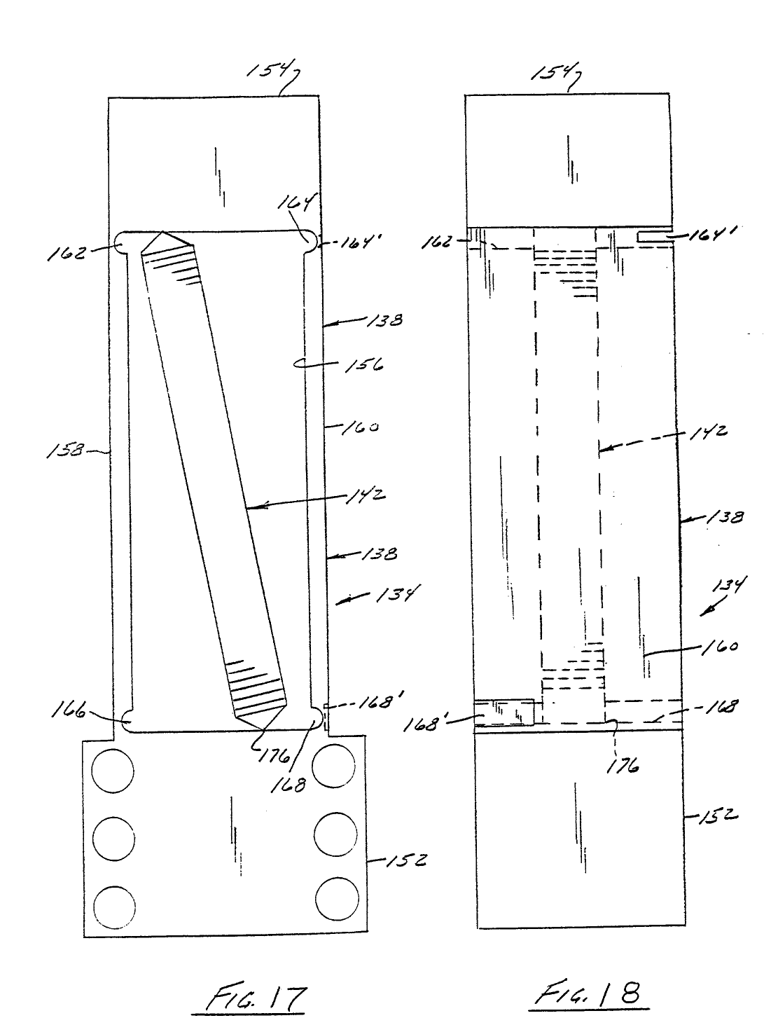

The effects of material removal or thinning can also be done by adding material to the flexure frame 138 and thereby increasing the flexure's resistance to stretching and compression and increasing its spring constant instead of or in addition to removing material from it. Hence, referring to FIGS. 19 and 20, material could be added to the flexure frame 138 either by filling in part or all of a flex notch as illustrated at 164″ or by welding or otherwise attaching material to the flexure frame 138 adjacent a desired flex notch as illustrated at 168″.

ii. Guide Arrangement

Considerable time and effort are required to remove material from the flexure frame 138 or to add material to the flexure frame 138. Moreover, removing material necessarily weakens the flexure frame 138 to the point that there may be concern about fatigue limit on the material. Hence, it may be desirable in many applications to employ a guide structure instead of or in addition to thinning or thickening flex notches.

A preferred guide structure 400 for use in a single element or flexure stage 134 is illustrated in FIGS. 10,11, and 11A. Guide arrangement 400 preferably includes a set of guide wires 402 and 404 attached to the free end 154 of the flexure stage 134. Two parallel guide wires 402 and 404 are provided in the illustrated embodiment—one adjacent each lateral end of the upper horizontal edge of the free end 154. Both guide wires 402 and 404 extend orthogonally to the XY plane or in the Z direction. The wires 402 and 404 are attached to the free end 154 by way of a T-shaped support bar 406 that extends in parallel with the X axis. Specifically, the wires 402 and 404 extend through respective slots 408 and 410 in the bar 406 and are fixed in the slots by depositing a bead 424 or 426 of epoxy or some other adhesive into the slot 408 or 410. The free ends of each wire 402 or 404 are attached to a rigid support structure 422, preferably the same structure to which the fixed end 152 of the flexure stage 134 is attached, by way of tubular wire holders 414, 416 and set screws 418, 420. The set screws 418 and 420 preferably comprise allen screws threaded radially through the wire holders 414 and 416 and into locking engagement with the ends of the wires 402 and 404. The wires 402 and 404 are placed under tension so that they impart considerable resistance to both pitching and rolling of the flexure stage free end 154. However, they do not impart significant resistance to movement in the XY plane because they extend in the Z direction and are flexible. The wire holder could be piezoelectric or controllable in some other manner and could be driven by a voltage from the scan controller, or a feedback system of another kind, to keep the out-of-plane and/or off-axis motion to a minimum by changing the tension on individual wires. The appropriate voltage waveform to perform this correction could be learned by putting sensors on the free end, as mentioned above, and making the voltage such that over a scan the free end's out-of-plane and/or off-axis motion is minimized. The wire itself may also be electrostrictive or thermostrictive, rather than or in addition to the wire holder.

The flexure stage 134 could be attached to the nominal center of each wire 402 or 404 without giving further consideration to additional flexure stage tuning or trimming. However, if desired, additional tuning or trimming could be achieved by moving the clamping point longitudinally with respect to the center of the wire 402 or 404 so that, upon flexure stage twisting, unequalized forces are imposed on the flexure stage 134 due to the unequal distance between the flexure stage 134 and the ends of the wires 402 and 404. This fine tuning could be achieved by changing the location at which the wire 402 or 404 is glued to the bar 406 and/or by changing the position of the pinning points at which the ends of the wires 402 and 404 are pinned or screwed to the wire holders 414 and 416.

In addition to the other advantages described above, employing a guide structure to reduce flexure stage pitch and roll also has the advantage of increasing the stiffness of the moving portion of the flexure stage. This added stiffness increases the resonant frequency of the flexure stage 134 and hence increases the speed at which the instrument may be operated.

Different guide configurations could be used in different applications. For instance, in a “mirror-image” arrangement of the type described in Section 2 above, in which the free ends of two flexure elements are mounted end to end, wires could be attached to the opposite lateral sides of the common free end of the mirrored flexure elements. Any guide structure could be used, as long as it is stiff in the Z direction and flexible in the X direction.

Alternatively, and referring to FIG. 12, a wire guide structure 500 that incorporates an additional wire 503 could be attached to the vertex 52 of an X-Y flexure stage 30 in parallel with the wires 502 and 504 attached to the free end 54 of the X stage 34. This additional wire 503 arrests the vertex 52 of the flexure stage 30 from Z displacement and pitch and roll. FIG. 12 also illustrates an alternative technique for attaching the wires 502 and 504 to the bar 506. In this embodiment, the wires 502 and 504 extend through bores 508 and 510 extending through the bar 506 rather than being received in slots. It is not shown, but set screws or other adjustable means could be used to fix wires 502 and 504 to bar 506. Of course, the bar 506 could be replaced with the bar 406 of the previous embodiment or any other suitable structure for attaching the wires 502 and 504 to the flexure stage 30. A similar bar could be used to attach wire 503 to the vertex 52.

The wire guide structure 400 has proven very effective at reducing flexure stage pitch and roll, but it still is capable of removing only a percentage of total out-of-plane motion. Even in those applications where it is preferred over varying the geometry of the flexure stage 134, it is still desirable to first optimize the flexure stage 134 by changing the orientation of the piezo stack 142 within the flexure frame 138 and by then further tuning the flexure stage 134 using the wire guide structure 400.

iii. Multiple Piezo Stacks

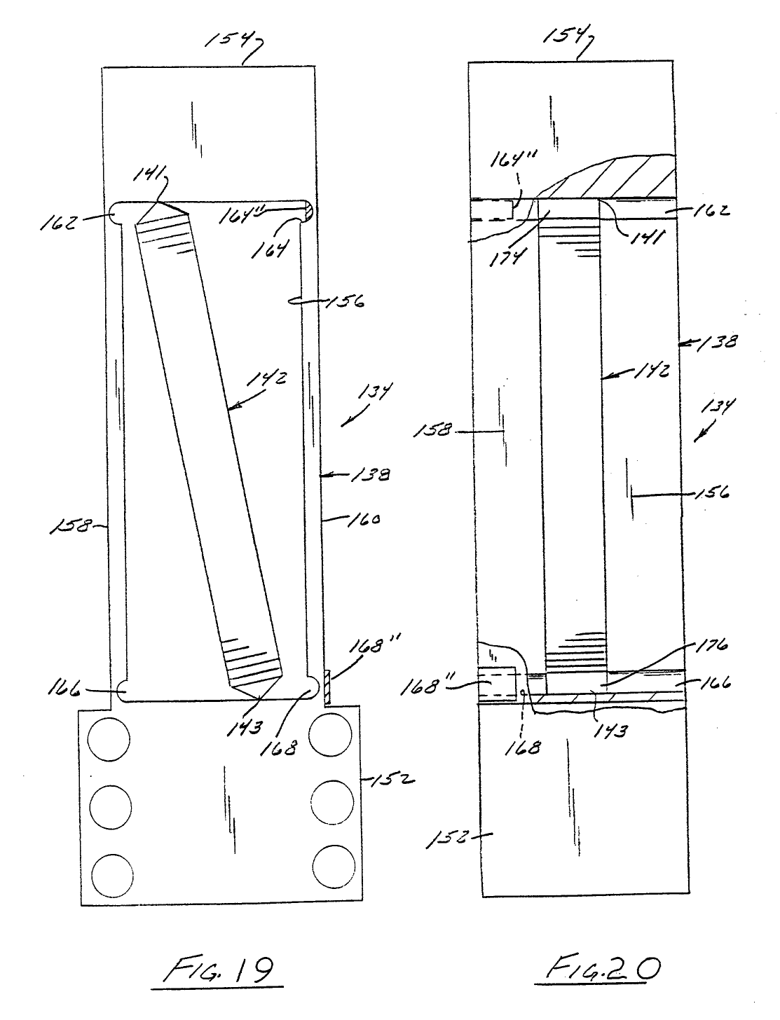

Referring now to FIGS. 21 and 22, still another way of eliminating at least some out-of-plane motion components is to install a second piezo stack 142′ or other actuator on the flexure frame 138 to act in concert with the piezo stack 142 to reduce net out-of-plane force components imparted by the first piezo stack 142. (The term “net” out-of-plane force components is employed to reflect the fact that the piezo stack 142 could impose force components solely within the XY plane but that misalignments between the piezo stack 142 and the flexure frame 138 and other considerations could combine to cause the net forces as experienced by the free end 154 of the flexure to include out-of-plane components.)

According to this technique, the first piezo stack 142 is first mounted on the flexure frame 138 in a manner so as to minimize the out-of-plane force components imposed by it, i.e., by orientating it such that its worst bowing component is within the XY plane and possibly by altering its orientation and/or geometry to reduce other bowing components. A second piezo stack 142′ or other actuator then is mounted on the flexure frame 138 and positioned so that out-of-plane force components imposed by it tend to offset the net out-of-plane force components imposed by the first piezo stack 142 so that the net out-of-plane force components imposed by both piezo stacks 142 and 142′ is approximately zero. In the illustrated embodiment in which the piezo stack 142 is mounted in a cavity 156 of the flexure stage 134, the second piezo stack 142′ is typically mounted in the same cavity 156 at a different orientation than the first piezo stack 142 with respect to the Z axis and possibly in a different orientation with respect to the X axis. As needed, and as space allows, more than two actuators could be used in this manner.

Like the other techniques described above, determining the optimum location of the second piezo stack 142′ is typically performed by trial and error in a closed-loop fashion.

This technique offers the advantage of being somewhat retrofittable because it may not require any alteration to the orientation or structure of either the piezo stack 142 or the flexure frame 138 after initial assembly. It exhibits the disadvantage, however, of being somewhat expensive to implement because it requires a second piezo stack 142′. This technique also usually proves less than fully effective at removing all net out-of-plane force components and hence in practice still would likely have to be combined with one or more of the other techniques described above including the use of guide wires, flexure stage thinning or thickening, etc.

Although the invention has been disclosed and described with respect to several preferred embodiments, many changes and modifications could be made to the invention without departing from the spirit thereof.

For instance, as discussed above, the various techniques for trimming or tuning a flexure stage are not mutually exclusive, but in practice would be combined with each other and possibly with other techniques to reduce out-of-plane motion to within acceptable parameters.

5. Alternative Applications

As discussed above, the invention is not limited to use with flexure stages of the disclosed type. It instead is applicable to virtually any positioning apparatus in which an actuator is used to translate a free end of the apparatus with respect to a fixed end within a desired path.

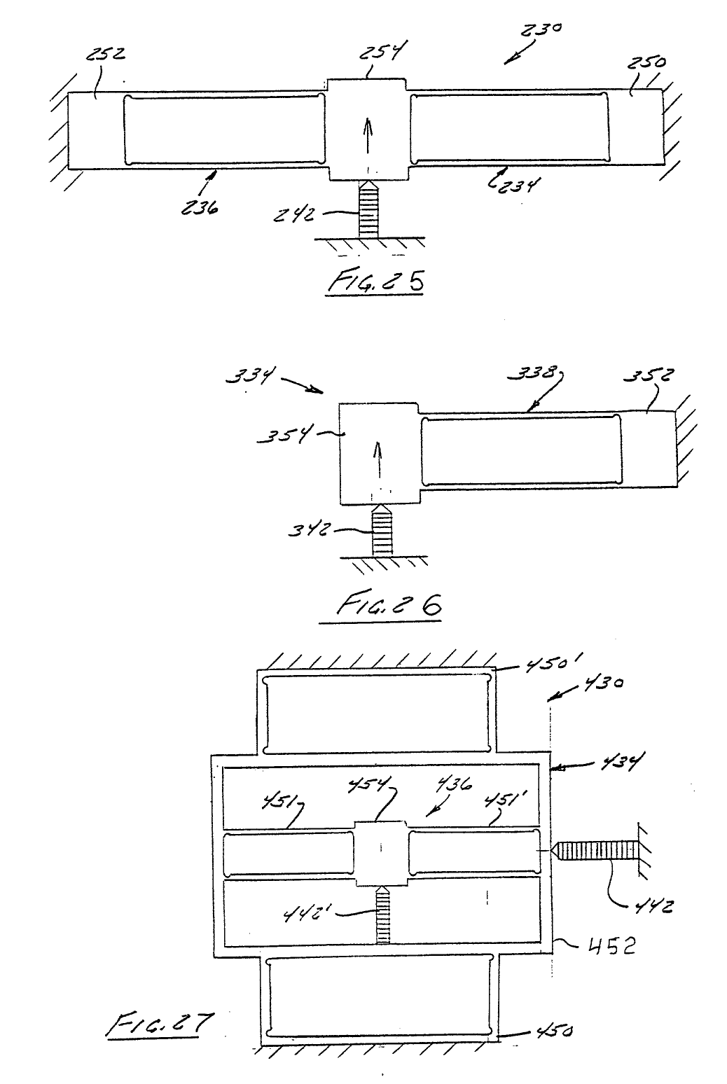

For instance, an example of a double-ended flexure 230 with which the invention is applicable is illustrated in FIG. 25. Double-ended flexure 230 includes first and second flexure elements 234 and 236 mounted end to end such that they share a common free end 254 disposed intermediate their fixed ends 250 and 252. An external piezo stack 242 acts on the free end 254 to drive it to effect linear movement along the X-axis as represented by the arrow in FIG. 25.

FIG. 26 illustrates a single ended flexure stage 334 configured for a single X-axis of motion. The flexure stage 334 includes a flexure frame 338 having a fixed end 352 and a free end 354. An external piezo stack 342 acts on the free end 354 to effect linear movement along the X-axis as represented by the arrow in FIG. 26.

FIG. 27 illustrates a double ended flexure stage 430 configured to effect motion along both the X-axis and the Y-axis. The flexure stage 430 includes a first flexure element 434 and a second flexure element 436 disposed within the first flexure element 434. The first flexure element 434 includes a center free end 452 (formed from a generally rectangular frame in the illustrated embodiment) and a pair of opposed fixed ends 450 and 450′. The second flexure element 436 is of similar construction but extends orthogonally with respect to the first flexure element 434 so that its fixed ends 451 and 451′ are fixed to sidewalls of the free end 452 of the first flexure element 434 and such that its free end 454 is disposed between the fixed ends 451 and 451′. A sensor or other workpiece is mounted on the free end 454 of the second flexure element 436. Movement of this workpiece along the Y-axis is effected by way of a first, external piezo stack 442 engaging the sidewall of the first flexure element free end 452. Movement of the workpiece along the X-axis is effected by way of a second piezo stack 442′ disposed within the first flexure element free end 452 and acting on the bottom surface of the second flexure element free end 454.

Virtually all of the flexure tuning techniques described in Section 4 above are usable either alone or in combination with one another on each of the flexure stages of FIG. 25, FIG. 26, and FIG. 27 or on virtually any other flexure stage.

The scope of these and other changes will become apparent from the appended claims.

We claim:

1. A method comprising:
(A) imposing a force on a flexure stage to attempt to drive a free end of said flexure stage to move along a desired path;
(B) detecting motion of a portion of said flexure stage out of said desired path; and then
(C) adjusting an operational parameter of said flexure stage to reduce motion of said free end out of said desired path.

2. A method as defined in claim 1, wherein said flexure stage includes
a flexure frame which has said fixed end and said free end, and
an actuator which imposes said force on said flexure frame.

3. A method as defined in claim 2, wherein
a portion of said actuator contacts a peripheral surface of said flexure frame at a first location during said detecting step, and wherein
said adjusting step comprises reducing net force components imposed out of said desired path by said actuator during imposition of said force by moving said portion of said actuator to a position in which said portion contacts said peripheral surface at a second location that is spaced from said first location by a distance which reduces motion of said free end out of said desired path upon said subsequent imposition of said force by said actuator.

4. A method as defined in claim 2, wherein flex notches are formed in peripheral surfaces of said flexure frame to promote movement of said free end along said desired path, and wherein said adjusting step comprises adjusting a resistance to motion of said flexure frame out of said desired path by adjusting the depth of at least a portion of at least one of said flex notches by a distance which reduces the motion of said free end along said desired path upon said subsequent imposition of said force.

5. A method as defined in claim 2, wherein flex notches are formed in peripheral surfaces of said flexure frame to promote movement of said free end along said desired path, and wherein said adjusting step comprises adjusting a resistance to motion of said flexure frame out of said desired path by adjusting the spring constant of at least a portion of said flexure frame.

6. A method as defined in claim 2, wherein said actuator comprises a first actuator, and wherein said adjusting step comprises compensating for the detected motion out of said desired path by operating a second actuator to impose a net force component out of said desired path that at least substantially offsets a net force component imposed out of said desired path by said first actuator.

7. A method as defined in claim 2, wherein
said actuator comprises a first actuator;
said flexure stage includes a second actuator; and
said adjusting step comprises compensating for the detected motion out of said desired path by operating said second actuator to impose a force component out of said desired path on said flexure frame that at least substantially offsets a net force component imposed out of said desired path by said first actuator.

8. A method as defined in claim 2, wherein
a portion of said actuator contacts a peripheral surface of said flexure frame during said detecting step, and wherein
said adjusting step comprises reducing net force components imposed out of said desired path by said actuator by altering an area of said portion by an amount which reduces the motion of said free end out of said desired path upon said subsequent imposition of said force by said actuator.

9. A method as defined in claim 1, wherein said adjusting step comprises engaging a portion of said flexure stage with a guide that imparts significant resistance to any motion of said free end out of said desired path but which does not impart significant resistance to motion of said free end along said desired path.

10. A method as defined in claim 9, wherein the resistance imparted by said guide is controlled by an actuator which is driven by a signal to keep motion out of said desired path small.

11. A method as defined in claim 9, wherein said guide comprises a wire which has (1) a generally central portion attached to said free end, and (2) at least one fixed end.

12. A method as defined in claim 1, wherein said flexure stage comprises a flexure frame and an actuator mounted on said flexure frame, and further comprising
prior to assembling said flexure stage, determining a bowing plane in which non-axial force components out of said desired path imposed upon operation of said actuator are the greatest, and then
during assembly of said flexure stage, mounting said actuator on said flexure frame such that said bowing plane is located at least primarily in a plane that contains said desired path.

13. A method as defined in claim 1, wherein
said flexure stage comprises a flexure frame and an actuator mounted on said flexure frame, and wherein
said adjusting step comprises repositioning said actuator relative to said flexure frame to reduce bowing motion of said flexure stage frame in a plane that contains said desired path, and adjusting at least one other operational parameter of said flexure stage to as to eliminate pitching and rolling motion of said flexure stage relative to said plane.

14. A method comprising:
(A) providing a flexure stage including:
(1) a flexure frame having a fixed end and a free end which is movable relative to said fixed end, and
(2) an actuator which engages said flexure frame; then
(B) operating said actuator to apply a force to said flexure frame to attempt to drive said free end to move in a desired path;
(C) detecting motion of said free end out of said desired path; and then
(D) adjusting an operational parameter of said flexure stage to reduce motion of said free end out of said desired path upon subsequent imposition of said force by said actuator.

15. A method comprising:
(A) providing a flexure stage including:
(1) a flexure frame having a fixed end, a free end which is movable relative to said fixed end, and a cavity formed therein between said fixed end and said free end, said cavity being bordered by an inner laterally extending end surface disposed proximate said fixed end, an outer laterally extending end surface disposed proximate said free end, and a pair of laterally-opposed surfaces extending longitudinally from said inner end surface to said outer end surface, each of said laterally-opposed surfaces having first and second flex notches formed therein proximate respective ends thereof, and
(2) a piezo stack positioned in said cavity and extending from said inner end surface to said outer end surface, said piezo stack having an inner end which engages said inner end surface along a first line of contact and an outer end which engages said outer end surface along a second line of contact, said first and second lines of contact being parallel to one another; then
(B) energizing said piezo stack to impose a force on said flexure stage frame to attempt to drive said free end to move in a plane that extends substantially orthogonally with respect to said first and second lines of contact, wherein movement of said free end in said plane is facilitated by said flex notches; then
(C) detecting motion of said free end out of said plane; and then (D) adjusting an operational parameter of said flexure stage to at least substantially prevent motion of said free end out of said plane upon subsequent imposition of said force by said piezo stack.

16. A method comprising:
(A) providing a flexure stage including
(1) a flexure frame which has a fixed end and a free end which is movable relative to said fixed end, wherein peripheral surfaces of said flexure frame have notches formed therein to facilitate movement of said free end along a desired path, and
(2) an actuator; then
(B) operating said actuator to impose a force on said flexure frame to attempt to drive said free end to move along said desired path;
(C) detecting motion of said free end out of said desired path, and then
(D) adjusting the depth of at least a portion of at least one of said flex notches by an amount which at least significantly reduces the motion of said free end out of said desired path upon subsequent imposition of said force by said actuator.

17. A method comprising:
(A) providing a flexure stage including
(1) a flexure frame which has a fixed end and a free end which is movable relative to said fixed end, wherein peripheral surfaces of said flexure frame have flex notches formed therein to facilitate movement of said free end along a desired path, and
(2) an actuator; then
(B) operating said actuator to impose a force on said flexure frame to attempt to drive said free end to move along said desired path;
(C) detecting motion of said free end out of said desired path; and then
(D) adjusting the spring constant of at least a portion of said flexure frame by an amount which at least significantly reduces the motion of said free end out of said desired path upon subsequent imposition of said force by said actuator.

18. A method as defined in claim 17, wherein said adjusting step comprises at least one of (1) adding material to at least one flex notch, (2) removing material from at least one flex notch, and (3) adding or removing material to said flexure frame at a location near at least one flex notch.

19. A method comprising:
(A) providing a flexure stage including
(1) a flexure frame which has a fixed end and a free end which is movable with respect to said fixed end, and
(2) an actuator which contacts a peripheral surface of said flexure frame at a first location; then
(B) operating said actuator to impose a force on said flexure frame to attempt to drive said free end to move along a desired path;
(C) detecting motion of said free end out of said desired path; and then
(D) moving said portion of said actuator to a position in which said portion contacts said peripheral surface of said flexure frame at a second location that is spaced from said first location by a distance which at least significantly reduces the motion of said free end out of said desired path upon subsequent imposition of said force by said actuator.

20. A method as defined in claim 19, wherein said moving step reduces bowing motion of said flexure stage out of said desired path, and further comprising adjusting another operational parameter of said flexure stage so as to eliminate pitching and rolling motion of said flexure stage out of said desired path.

21. A method comprising:
(A) providing a flexure stage including a flexure frame which has a fixed end and a free end which is movable relative to said fixed end;
(B) operating a first actuator to impose a force on said flexure stage frame to attempt to drive said free end to move along a desired path;
(C) detecting motion of said free end out of said desired path upon operation of said first actuator;
(D) providing a second actuator; and
(E) simultaneously operating said first and second actuators such that a net force component imposed out of said desired path by said second actuator at least partially offsets a net force component imposed out of said desired path by said first actuator.

22. A method comprising:
(A) providing a flexure stage including
(1) a flexure frame which has a fixed end and a free end which is movable relative to said fixed end, and
(2) an actuator; then
(B) operating said actuator to impose a force on said flexure frame to attempt to drive said free end to move along a desired path; and
(C) resisting motion of said free end out of said desired path with a guide which is attached to said flexure frame and which does not impart significant resistance to motion of said free end within said desired path.

23. A method as defined in claim 22, wherein said resisting step comprises resisting the motion out of said desired path with a guide wire which is connected to said flexure frame.

24. A method as defined in claim 22, wherein said guide wire is a first guide wire located proximate a first lateral side of said flexure frame, and further comprising a second guide wire which is connected to said flexure frame and which is located proximate a second lateral side of said flexure frame located remote from said first lateral side, said first and second guide wires, in combination, resisting twisting motion of said free end relative to said desired path.

25. A method comprising:
(A) providing a flexure stage including
(1) a flexure frame which has a fixed end and a free end which is movable relative to said fixed end, and
(2) an actuator having a portion which contacts a peripheral surface of said flexure frame; then
(B) operating said actuator to impose a force on said flexure frame to attempt to drive said free end to move along a desired path;
(C) detecting motion of said free end out of said desired path; and then
(D) altering an area of said portion by an amount which at least significantly reduces the motion of said free end out of said desired path upon subsequent imposition of said force by said actuator.

26. A method as defined in claim 25, wherein the altering step comprises removing material from said portion.

27. A flexure stage comprising:
(A) a flexure frame having a fixed end and a free end which is movable with respect to said fixed end; and
(B) an actuator which is operable to drive said free end to move in a desired path relative to said fixed end, at least one of said actuator and said flexure frame incorporating measures to reduce motion of said free end out of said desired path upon operation of said actuator.

28. A flexure stage as defined in claim 27, wherein said flexure stage is a single-axis flexure stage in which said fixed end is attached to a support structure and a workpiece is moved by said free end.

29. A flexure stage as defined in claim 27, wherein
said flexure stage is a two-axis flexure stage having first and second flexure elements,
said free end and said fixed end are a free end and a fixed end, respectively of said first flexure element,
said fixed end of said first flexure element is rigidly coupled to a free end of said second flexure element, and wherein
said fixed end of said second flexure element is attached to a support structure.

30. A flexure stage comprising:
(A) a flexure frame having a fixed end, a free end which is movable along a desired path relative to said fixed end, and a cavity formed therein between said fixed end and said free end, said cavity being bordered by an inner laterally extending end surface disposed proximate said fixed end, an outer laterally extending end surface disposed proximate said free end, and a pair of laterally-opposed surfaces extending longitudinally from said inner end surface to said outer end surface, each of said laterally-opposed surfaces having first and second flex notches formed therein proximate respective ends thereof; and
(B) a piezo stack positioned in said cavity and extending from said inner end surface to said outer end surface, said piezo stack having an inner end which engages said inner end surface along a first line of contact and an outer end which engages said outer end surface along a second line of contact, said first and second lines of contact being parallel to one another, at least one of said piezo stack and said flexure frame incorporating measures to at least substantially prevent motion of said free end out of said desired path upon operation of said piezo stack.

31. A flexure stage comprising:
(A) a flexure frame which has a fixed end and a free end which is movable relative to said fixed end, wherein
peripheral surfaces of said flexure frame have flex notches formed therein to promote movement of said free end along a desired path, said notches having a length extending said desired path and having a depth extending away from said desired path, and wherein
the depth of at least one of said notches is nonuniform such that said free end exhibits greater resistance to motion in one direction with respect to said desired path than in another direction with respect to said desired path; and
(B) an actuator which is selectively operable to drive said free end.

32. A flexure stage comprising:
(A) a flexure frame which has a fixed end and a free end which is movable in a desired path relative to said fixed end;
(B) a first actuator which imposes a force on said flexure frame; and
(C) a second actuator which imposes a force on said flexure frame, said second actuator imposing a net force component said desired path, wherein said net force component at least substantially offsets a net force component out of said desired path imposed by said first actuator.

33. A flexure stage comprising:
(A) a flexure frame which has a fixed end and a free end which is movable along a desired path relative to said fixed end;
(B) an actuator which imposes a force on said flexure frame; and
(C) a guide which is attached to said flexure frame and which imparts substantial resistance to motion of said free end out of said desired path.

34. A flexure stage as defined in claim 33, wherein said guide comprises a guide wire which is connected to said flexure frame.

35. A flexure stage as defined in claim 34, wherein said guide wire has (1) a central portion connected to said free end, and (2) at least one end attached to a fixed support.

36. A flexure stage as defined in claim 34, wherein said guide wire is a first guide wire located proximate to a first lateral side of said flexure frame, and further comprising a second guide wire which is connected to said flexure frame and which is located proximate a second lateral side of said flexure frame located remote from said first lateral side, said first and second guide wires, in combination, resisting twisting motion of said free end relative to said desired path.

37. A flexure stage as defined in claim 34, wherein said flexure stage is formed from two interconnected flexure elements extending at an angle from a common vertex that is located between said fixed end and said free end, and wherein said guide comprises first and second wires, said first wire being operatively coupled to said flexure stage proximate said free end, and second guide wire being operatively coupled to said flexure stage proximate said vertex.

38. A flexure stage as defined in claim 37, wherein said guide further comprises a third wire extending in parallel with said first and second wires and operatively coupled to said flexure stage proximate said free end.

39. A flexure stage comprising:
(A) a flexure frame which has a fixed end and a free end which is movable along a desired path relative to said fixed end; and
(B) an actuator which is selectively operable to drive said free end, wherein a portion of said actuator contacts a peripheral surface of said flexure frame, and wherein the area of said portion is selected to reduce motion of said free end out of said desired path.
